(19) United States
(12) Patent Application Publication
(10) Pub. No.: US 2025/0087456 A1
(43) Pub. Date: Mar. 13, 2025

(54) HIGH SELECTIVITY AND UNIFORM DIELECTRIC ETCH

(71) Applicant: Lam Research Corporation, Fremont, CA (US)

(72) Inventors: Sriharsha Jayanti, Fremont, CA (US); Hsu-Cheng Huang, Newark, CA (US); Gerardo Adrian Delgadino, Milpitas, CA (US); Merrett Wong, San Carlos, CA (US); Nikhil Dole, Castro Valley, CA (US)

(21) Appl. No.: 18/725,503

(22) PCT Filed: Jan. 10, 2023
(86) PCT No.: PCT/US2023/060400

§ 371 Date: Jun. 28, 2024

Related U.S. Application Data
(60) Provisional application No. 63/299,402, filed on Jan. 13, 2022.

(51) Int. Cl. H01J 37/32; H01L 21/3065

(52) U.S. Cl. CPC H01J 37/32091; H01J 37/32449; H01J 37/32724; H01L 21/3065

(57) ABSTRACT

Various embodiments herein relate to methods and apparatus for etching a feature in a substrate. Often, the feature is etched in the context of forming a DRAM or other memory device. The feature is etched in dielectric material, which often includes a silicon oxide. The feature is etched using chemistry that includes a metal-containing gas such as tungsten hexafluoride. Although other metal-containing gases are commonly used as deposition gases (e.g., to deposit metal-containing films), they can also be used during etching. Advantageously, the inclusion of a metal-containing gas in the etch chemistry can increase the selectivity of the etch and/or improve the feature-to-feature uniformity (e.g., improve LCDU).

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### FIELD

Embodiments herein relate to methods and apparatus for fabricating a semiconductor device, and more particularly, for etching high aspect ratio features into dielectric material with a high degree of selectivity with respect to a mask material that defines the features.

### BACKGROUND

One process frequently employed during fabrication of semiconductor devices is formation of an etched cylinder or other recessed feature in dielectric material. For instance, such processes are commonly used in memory applications such as fabricating dynamic random access memory (DRAM) structures. As the semiconductor industry advances and device dimensions become smaller, such features are increasingly difficult to etch in a uniform manner, especially for high aspect ratio cylinders having narrow widths and/or deep depths.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Certain embodiments herein relate to methods and apparatus for etching a feature in dielectric material on a semiconductor substrate in the context of forming, e.g., a memory structure.

In one aspect of the disclosed embodiments pertains to methods of etching a feature in a substrate while fabricating an electronic device. Such methods may be characterized by the following operations: receiving the substrate on a substrate support in a reaction chamber, the substrate comprising a silicon and oxygen containing material under a mask layer having a pattern thereon; and exposing the substrate to a plasma in the reaction chamber to thereby etch the feature in the silicon and oxygen containing material. The plasma may be generated from a plasma generating gas comprising a metal-containing gas, one or more fluorocarbons, and oxygen. The plasma may be a capacitively-coupled plasma and the substrate may be biased. The capacitively coupled plasma may be generated at an excitation frequency between about 13-169 MHz at an RF power level of about 9 kW or less per substrate or about 6 kW or less per substrate. The substrate may be biased at a bias frequency between about 50 kHz and 10 MHz at an RF power level of about 40 kW or less per substrate, about 30 kW or less per substrate, or about 20 kW or less per substrate. In some embodiments, the metal containing gas is metal-containing halide such as a metal fluoride. Examples include tungsten hexafluoride, rhenium hexafluoride, molybdenum hexafluoride, tantalum pentafluoride, vanadium fluoride, and any combination thereof. In some implementations, the metal-containing gas is a tungsten-containing gas such as tungsten hexafluoride.

In certain embodiments, the capacitively coupled plasma is generated at an RF power level of about 0.2 kW or less per substrate. In certain embodiments, the capacitively coupled plasma is generated at an RF power level of about 0.1 kW or less per substrate. In certain embodiments, the substrate is biased at an RF power level of about 0.5 kW or less per substrate. In certain embodiments, the substrate is biased at an RF power level of about 0.3 kW or less per substrate. In certain embodiments, the excitation frequency is about 60 MHz and the bias frequency is about 400 kHz.

In some examples, the plasma generating gas comprises about 0.01 to 10% by volume metal-containing gas. In certain embodiments, the plasma generating gas comprises C₄F₈. In certain embodiments, the substrate support is maintained at a temperature about −100° C. to 150° C. or about −30° C. to 150° C. while the substrate is exposed to the plasma.

In certain embodiments, the silicon and oxygen containing material comprises silicon oxide. In some implementations, the mask layer comprises carbon, polysilicon, silicon nitride, silicon oxynitride, or any combination thereof.

In certain embodiments, the feature has a critical dimension of about 200 nm or less. In some implementations, the etching produces a plurality of features having a feature density of about 1/200 nm⁻¹ or greater in at least one direction. In some implementations, the feature is etched with a selectivity of the silicon and oxygen containing material to the mask of at least about 0.3. In some implementations, the etching produces a plurality of features and the plurality of features have a local critical-dimension uniformity (defined as an integer multiple of the standard deviation or the range [max CD-min CD] of the CDs). In some cases, a listed range of LCDU values corresponds to LCDU=the sample standard deviation (s) of the CDs of the plurality of features (which is a population of etched features). As examples, the LCDU may be about 200 Å or less, about 100 Å or less, about 50 Å or less, or about 20 Å or less, or about 15 Å or less, or about 10 Å or less, or about 5 Å or less.

In certain embodiments, the metal-containing gas dissociates in the plasma into metal-containing fragments and halogen-containing fragments (e.g., fluorine-containing fragments).

In certain embodiments, the electronic device comprises a memory device.

In many cases, the flow rate of the metal-containing gas in the plasma generating gas is relatively low. For example, in some cases the flow rate of the metal-containing gas (e.g., a metal halide) in the plasma generating gas may be about 20 sccm or less. In some cases, flow rate of the metal-containing gas (e.g., a metal halide) in the plasma generating gas may be about 10 sccm or less. In certain cases, the flow rate of the metal-containing gas (e.g., a metal halide) in the plasma generating gas is about 2 sccm or less. Process gas flow rates and plasma power values are recited for processing a single 300 mm wafer. For processing larger or smaller substrates or processing multiple substrates concurrently, these values may be scaled as appropriate.

The method may achieve one or more benefits. For example, in various embodiments, the method provides an etch selectivity of at least about 0.3 or at least about 1, the selectivity being defined as an etch rate of the silicon oxide divided by an etch rate of the mask layer, where the mask comprises carbon, polysilicon, silicon nitride, silicon oxynitride, or any combination thereof.

In another aspect of the disclosed embodiments, an apparatus for etching a feature in dielectric material on a substrate while fabricating a memory structure is provided, the apparatus including: a reaction chamber including: an inlet for introducing process gases to the reaction chamber, an outlet for removing material from the reaction chamber, a substrate support, and a plasma source configured to provide a plasma to the reaction chamber, the plasma being a capacitively coupled plasma; and a controller configured to cause: receiving the substrate on the substrate support and exposing the substrate to a plasma in the reaction chamber to thereby etch the feature in the dielectric material. The controller may be additionally configured to produce the following actions: the plasma is generated from a gas comprising a metal-containing gas, one or more fluorocarbons, and oxygen; the plasma is a capacitively-coupled plasma and the substrate may be biased; the capacitively coupled plasma is generated at an excitation frequency between about 13-169 MHz at an RF power level of about 9 kW or less per substrate or about 6 kW or less per substrate; and the substrate is biased at a bias frequency between about 50 kHz and 10 MHz at an RF power level of about 40 kW or less per substrate, about 30 kW or less per substrate, or about 20 kW or less per substrate.

These and other features will be described below with reference to the associated drawings.

### BRIEF DESCRIPTION OF THE DRAWINGS

FIGS. 1A-1C depict a partially fabricated DRAM structure as a feature is etched into dielectric material.

FIG. 2 illustrates a partially etched feature that has become capped.

FIG. 3A is a flowchart describing a method of etching a feature for a DRAM structure according to certain embodiments.

FIGS. 3B and 3C depict a partially fabricated DRAM structure before and after the method of FIG. 3A.

FIG. 4 is a diagram of an etch system that may be employed to carry out etching of a substrate in accordance with certain embodiments disclosed herein.

### DETAILED DESCRIPTION

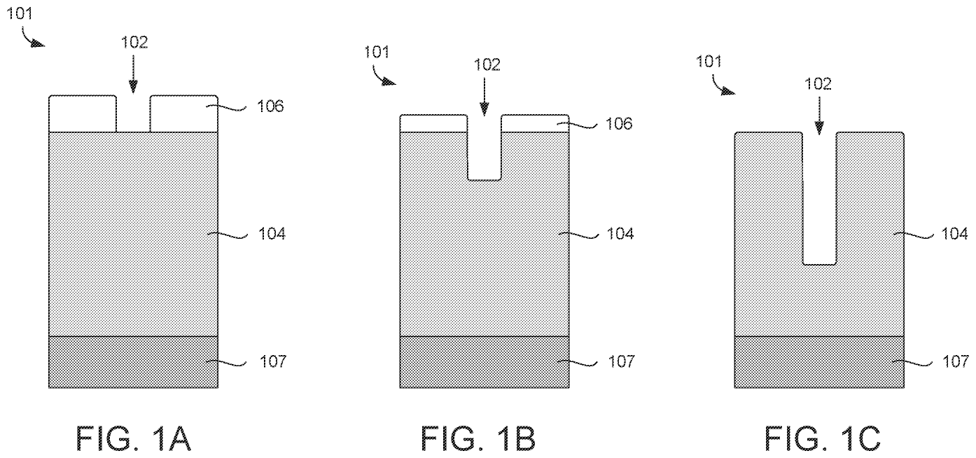

FIGS. 1A-1C depict in cross-section a partially fabricated structure such as a DRAM or other memory structure, which may be represented as a feature 102, which is etched into a dielectric material layer 104 on a substrate 101. The figures are not drawn to scale. FIG. 1A shows the substrate 101 before etching begins. The substrate includes a patterned mask layer 106 overlying the dielectric material layer 104. An underlying layer 107 is provided under the dielectric material layer 104. In various examples, the patterned mask layer 106 may have a thickness about 5 to 800 nm, and the dielectric material layer 104 may have a thickness of about 60 nm to 1.5 μm. The mask material may be comprised of carbon, polysilicon, silicon nitride, silicon oxynitride, any combination thereof, or another mask material known in the art. In some embodiments, the mask is comprised of two or more sub-layers, which may be different materials. The dielectric material layer 104 typically includes a silicon and oxygen containing material such as a silicon oxide (e.g., silicon dioxide). The underlying layer 107 may be a layer of silicon nitride, for example. In some cases, the dielectric material layer 104 may be a stack of materials including one or more layers of a silicon oxide and one or more layers of a silicon nitride. The one or more silicon nitride layers may be relatively thin compared to the one or more silicon oxide layers. In a particular example, the dielectric material layer 104 includes an upper layer of silicon nitride and a lower layer of silicon oxide (with the oxide being thicker than the nitride). In a similar example, the dielectric material layer 104 further includes a lower layer of silicon nitride, with the silicon oxide layer being sandwiched between the upper and lower layers of silicon nitride. The pitch between adjacent instances of feature 102 may be about 60 nm or less. In some embodiments, the feature density is about 1/60 nm⁻¹ or even more dense, which corresponds to a center-to-center feature separation of 60 nm or less. The critical dimension (e.g., diameter) of features including feature 102 may be about 200 nm or less, such as about 10 to 30 nm, or in some cases about 15 to 30 nm.

The substrate 101 shown in FIG. TA is provided to a semiconductor processing apparatus for etching. An appropriate apparatus is described below. After the substrate is introduced to the processing apparatus, a plasma is generated in the processing apparatus. The plasma may interact directly with the substrate to cause etching on the substrate. After a period of time, a feature 102 begins to form in the dielectric material layer 104, as shown in FIG. 1B. While the patterned mask layer 106 is somewhat resistant to the etching conditions, it still experiences some etching/erosion during this process. As such, the patterned mask layer 106 shown in FIG. 1B is thinner than the patterned mask layer 106 shown in FIG. TA.

FIG. 1C shows the substrate 101 just after the patterned mask layer 106 is substantially fully removed as a result of prolonged exposure to the etching conditions. At this point the feature 102 is deeper than the one shown in FIG. 1B, but it still does not extend all the way through the dielectric material layer 104. The feature 102 cannot be etched any deeper because the patterned mask layer 106 has been substantially fully removed. Any further etching would substantially erode the dielectric material layer 104 in an undesirable manner. FIGS. 1A-1C illustrate one of the problems frequently encountered when etching features. Often, various processing considerations limit the thickness of the mask layer that can be used for a particular application. This limits the depth of the features that can be formed using the patterned mask layer.

One technique for etching deeper holes without increasing the mask thickness is to increase the selectivity of the etch process. The selectivity is calculated as a ratio between the etch rate of the dielectric material and the etch rate of the mask material. For instance, if the dielectric material etches three times faster than the mask material, the etch process has a selectivity of 3:1. The selectivity of the etch process can be increased by increasing the etch rate of the dielectric material relative to the etch rate of the mask layer. Similarly, the selectivity can be increased by decreasing the etch rate of the mask layer relative to the etch rate of the dielectric material.

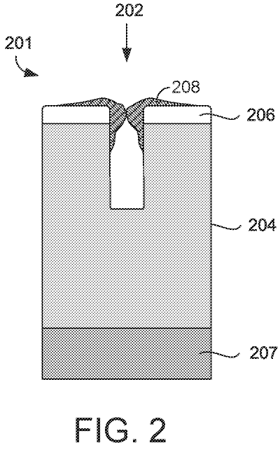

There are a number of techniques available for increasing the selectivity of the etch process. However, these techniques typically present other drawbacks such as an increase in capping. Capping is also referred to as etch stop, and it occurs when a recessed feature becomes blocked/clogged during an etch process. When a feature becomes clogged, no further etching is achieved for that feature. FIG. 2 illustrates a feature 202 which has become clogged during an etching process. The feature 202 is formed in a dielectric material layer 204, formed between an underlying layer 207 and a patterned mask layer 206. During etching, the etch chemistry interacts with the dielectric material layer 204 to remove the dielectric material and to form a fluorocarbon-based polymer 208 that deposits on the sidewalls of the feature 202. In many cases, the fluorocarbon-based polymer 208 deposits near the top of the feature 202. Where the deposition is substantial, it can cause the blocking/clogging problem illustrated in FIG. 2.

Many of the techniques that increase selectivity of the etch result in relatively greater fluorocarbon-based polymer formation on or near the patterned mask layer. This has the desirable effect of reducing the etch rate of the mask material, thereby increasing selectivity. However, this can also have the undesirable effect of capping when there is an excess of fluorocarbon-based polymer. In practice, the tradeoffs between selectivity and capping have limited how deep a high aspect ratio feature can be etched in dielectric material.

As the semiconductor industry aggressively scales feature density (e.g., pitch), the tolerance for feature-to-feature variation decreases. The features may be densely packed holes or ellipses (common in DRAM capacitor masks), or line and space patterns, generated with multi-patterning schemes or EUV lithography. Etching such dense features in dielectric layers (such as SiO₂) is often limited by not only selectivity to the mask but also high feature-to-feature variation, which may be represented as a parameter referred to as the local critical dimension uniformity (LCDU). LCDU may be defined by a multiple of the sample standard deviation, typically 1× or 3×, of the feature CDs, or LCDU may be defined by the range (max CD-min CD) of the feature CDs. Improving LCDU and increasing selectivity are becoming increasingly important. Examples of applications of the disclosed etch process include DRAM mask open and short contact applications.

Surprisingly, the inventors have developed a method of etching that improves both selectivity and LCDU. Such methods enable formation of high-density features while employing relatively thin mask layers. As such, the techniques described herein are advantageous for both etching dense features and for minimizing the amount of mask material required, without risk of capping the features.

In certain embodiments, process windows described herein provide an etch selectivity (dielectric vs. mask) of at least about 0.3 or at least about 1.0 or at least about 1.5. In certain case where masks define feature densities of at least about 1/60 nm⁻¹, process windows herein provide for LCDU values of at most about 200 Å, at most about 100 Å or less, at most about 50 Å, or at most about 20 Å, or at most about 15 Å, or at most about 10 Å, or at most about 5 Å (for LCDU defined as the sample standard deviation (s) of the CDs of the features in a population of etched features). Note that beneficial LCDU values may depend on the average size (e.g., CD) of the holes or other features under consideration. Generally, larger features exhibit larger values of LCDU. In certain embodiments having feature CDs of up to about 20 nm, LCDU values may be about 10 Å or less. In certain embodiments having feature CDs of about 200 nm or less, LCDU values may be about 100 Å or less.

Metal fluorides are sometimes used in a deposition gas, for example to form metal-based films using a vapor-based deposition process. Metal-containing gases are not conventionally used in etching. The addition of a metal-containing gas to the etch chemistry, when provided at an appropriate flow rate and under appropriate plasma conditions, increases the etch selectivity for dielectric material (e.g., silicon oxide in many cases) and/or reduces the feature-to-feature nonuniformity. This disclosure is not limited to any particular metal-containing gas. In various embodiments, the metal-containing gas comprises a metal-containing halide such as a metal fluoride. In some embodiments, the metal-containing gas comprises a tetravalent, pentavalent, or hexavalent metal fluoride. Examples of metal fluorides include tungsten fluorides (e.g., tungsten hexafluoride), rhenium fluorides (e.g., rhenium hexafluoride and rhenium heptafluoride), molybdenum fluorides (e.g., molybdenum tetrafluoride, molybdenum pentafluoride, and molybdenum hexafluoride), tantalum fluorides (e.g., tantalum pentafluoride), vanadium fluorides (e.g., vanadium tetrafluoride and vanadium pentafluoride), and any combination thereof. In some implementations, the metal-containing gas is a tungsten-containing gas such as tungsten hexafluoride. In many implementations, the metal-containing halide is a gas at the etch temperature. While one or more specific compounds may be used herein to facilitate the discussion. Unless otherwise clear from context, references to any specific compound may extend one or more other metal-containing gases such as those listed above.

One possible reason that metal-containing gases are not typically used in etching chemistry, particularly in the context of etching a recessed feature for a DRAM device, is that such features are not typically filled with metals or metal-containing materials. As such, any remaining metal, e.g., on the sidewalls or field region of the feature, could be problematic in future processing. Further, there may be a need to remove such materials before further processing can take place.

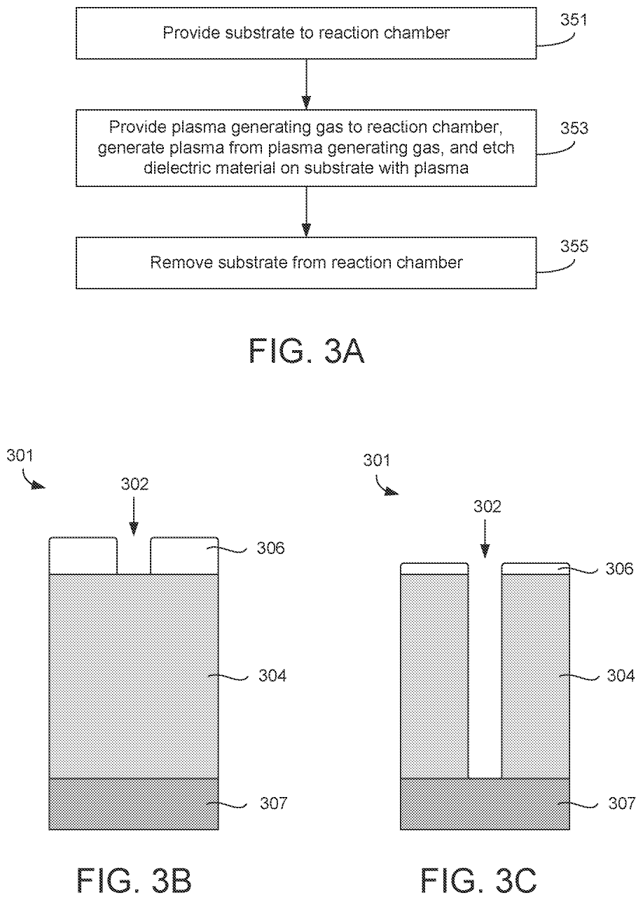

FIG. 3A is a flowchart describing a method of etching a feature in dielectric material according to certain embodiments. The method of FIG. 3A is described in the context of the structures shown in FIGS. 3B and 3C. FIGS. 3B and 3C illustrate a partially fabricated memory structure as a feature 302 is etched into a dielectric material layer 304 on a substrate 301. FIG. 3B shows the substrate 301 before etching begins, and FIG. 3C shows the substrate 301 after the etching is complete. The substrate may have dimensions as described above in relation to FIGS. 1A-IC. Similarly, the dielectric material layer 304 may have any of the structures/compositions described in relation to the dielectric material layer 104 of FIGS. 1A-IC. The substrate 301 includes a patterned mask layer 306 overlying the dielectric material layer 304. An underlying layer 307 is provided under the dielectric material layer 304. In certain examples, the patterned mask layer 306 is polysilicon, and may have a thickness of about 40 to 1000 nm, for example about 50 to 100 nm. In other examples, the patterned mask layer 306 is amorphous carbon, and may have a thickness of about 50 to 1200 nm, for example about 100 to 250 nm. Other mask materials may be used in some cases. In some examples, the dielectric material layer 304 includes a silicon oxide such as SiO₂. In some such cases, the dielectric material layer 304 is a single layer of silicon oxide (typically relatively thick). In some cases, the dielectric material layer 304 may include additional layers, for example one or more layers of silicon nitride, which may be interleaved between thicker layers of silicon oxide. The underlying layer 307 may be silicon nitride, for example. The final etch depth, as shown in FIG. 3C, is at the underlying layer 307.

The method of FIG. 3A begins with operation 351, where the substrate 301 shown in FIG. 3B is provided to a reaction chamber of a semiconductor processing apparatus. An appropriate apparatus is described further below. After the substrate is introduced to the reaction chamber, a plasma generating gas is provided to a reaction chamber, a plasma is generated from the plasma generating gas, and the plasma etches the dielectric material in operation 353.

The composition of the etch process gas may vary within certain ranges. In some embodiments, the flow rate of a metal fluoride or other metal-containing gas may be at least about 0.1 sccm, or at least about 0.2 sccm, or at least about 0.5 sccm, or at least about 1 sccm. In these or other cases, the flow rate of metal fluoride or other metal-containing gas may be about 20 sccm or less, for example about 10 sccm or less, or about 5 sccm or less, or about 2 sccm or less, or about 1 sccm or less.

The plasma generating gas also includes one or more materials conventionally used for etching dielectric material. Such materials commonly include fluorocarbons and hydrofluorocarbons such as C₃F₈, C₄F₈, C₄F₆, CH₂F₂, CH₃F, CHF₃, C₅F₈, C₆F₆, CF₄ etc. Such materials can also include oxidants such as O₂, O₃, CO, CO₂, COS, etc. An overall flow rate of the plasma generating gas may be between about 50-500 sccm in various cases. In some cases, one or more fluorocarbon sources may be mixed (prior to or after delivery to the reaction chamber), for example to provide a desired ratio of carbon and fluorine. The plasma generating gas may also include one or more inert species. In various cases, the metal fluoride or other metal-containing gas may represent at least about 0.01%, or at least about 0.05%, or at least about 0.1%, or at least about 0.5%, or at least about 1% of the volumetric flow rate of the plasma generating gas. In these or other cases, the tungsten hexafluoride or other metal-containing gas may represent about 10% or less, or about 5% or less, or about 1% or less, or about 0.05% or less, of the volumetric flow rate of the plasma generating gas. In some embodiments, in which the process gas comprises 02, CₓF_{y}, and a metal fluoride, the metal fluoride comprises about 0.01 to 10% by volume of the total process gas or about 0.1 to 10% by volume of the total process gas. The process gas may be delivered to the process chamber in a pulsed or unpulsed manner.

In a particular example, the plasma generating gas includes about 0.1 to 15 sccm metal-containing gas; it may also include about 0 to 50 sccm C₄F₆, about 0 to 70 sccm C₄F₈, about 0 to 70 sccm O₂, and between about 0-30 sccm CH₂F₂.

In various cases, the following conditions may be used to generate the plasma. The plasma may be a capacitively coupled plasma. The plasma may be generated at an excitation frequency between about 13-169 MHz, for example between about 40-100 MHz (e.g., 60 MHz in a particular case), at a power level of about 10 kW or less per 300 mm substrate. In some cases, the power level is relatively low, such as about OW-9 kW, or about OW-6 kW, or about 0.2 kW or less, or about 0.1 kW or less (all per 300 mm substrate). The plasma power may be pulsed or unpulsed.

A bias may be applied to the substrate, for example to promote a vertical etch rate. The bias may be applied to the substrate at a frequency between about 50 kHz and 10 MHz, or between about 200 kHz and 4 MHz (e.g., about 400 kHz in a particular case), at a power level of about OW to 40 kW per 300 mm substrate, about OW to 20 kW per 300 mm substrate, or about 1-20 kW per 300 mm substrate. In some cases, the power level used to bias the substrate is about 0.5 kW or less per 300 mm substrate or about 0.3 kW or less per 300 mm substrate. The substrate biasing plasma power may be pulsed or unpulsed.

The pressure within the reaction chamber may be about 1 to 100 mTorr or about 10 to 20 mTorr. In some cases, the pressure may remain relatively low during etching, but increase to a higher pressure (e.g., 100-500 mTorr, or 300-500 mTorr, or 400-500 mTorr) for a cleaning operation to clean the internal walls of the reaction chamber. The substrate support on which the substrate is provided may be maintained at a temperature (e.g., through heating and/or cooling) about −100° C. to 150° C. or about −30° C. to 100° C. In some cases, the substrate support is maintained at a temperature of at least about −20° C., or at least about 0° C., or at least about 20° C., or at least about 50° C., or at least about 60° C., or at least about 70° C. In these or other cases, the substrate support may be maintained at a temperature of about 150° C. or less, or about 120° C. or less, or about 100° C. or less, or about 80° C. or less, or about 50° C. or less, or about 20° C. or less, or about 0° C. or less, or about −20° C. or less, or about −50° C. or less. These temperatures may relate to the controlled temperature of the substrate support while the substrate is exposed to plasma.

After a period of time, a feature 302 begins to form in the dielectric material layer 304. After the feature reaches its final etch depth, as shown in FIG. 3C, the substrate 301 is removed from the reaction chamber in operation 355. As compared with conventional approaches, the method described in relation to FIGS. 3A-3C is capable of forming more uniform high-density features and/or deeper features without increasing the mask height. The inclusion of a metal fluoride or other metal-containing gas in the plasma generating gas, when provided at an appropriate flow rate and under appropriate plasma conditions, improves the selectivity of the etch. Advantageously, this improvement in selectivity does not increase the rate at which features become capped.

### Apparatus

The methods described herein may be performed by any suitable system and apparatus. A suitable apparatus includes hardware for accomplishing the process operations and a system controller having instructions for controlling process operations in accordance with the present embodiments. For example, in some embodiments, the hardware may include one or more process stations included in a process tool.

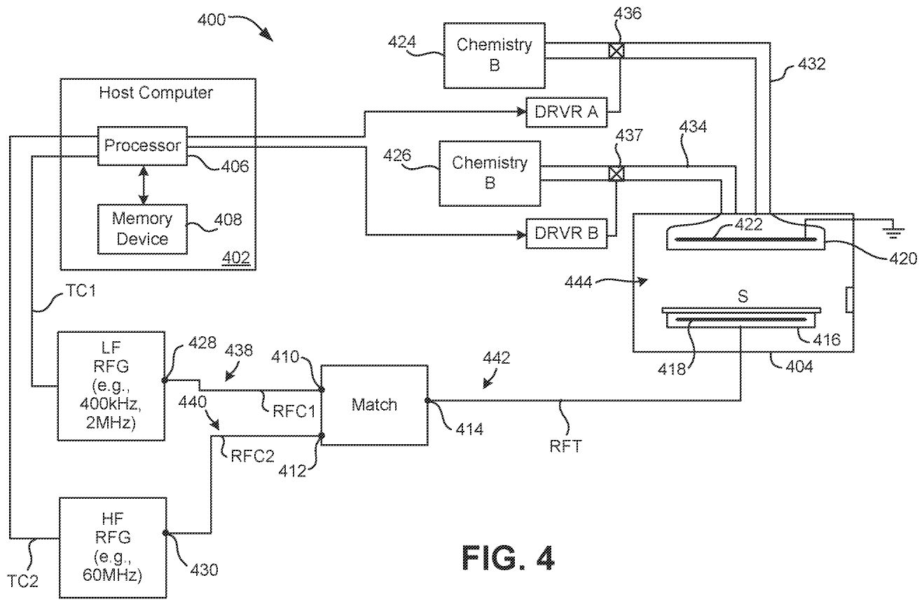

FIG. 4 is a diagram of an embodiment of a system 400 to illustrate performing etch processes such as those described herein. The system 400 includes a host computer 402, a low frequency (LF) radio frequency (RF) generator, a high frequency (HF) RF generator, a match, and a plasma chamber 404. As an example, the LF RF generator has an operating frequency of 400 kilohertz (kHz) or 2 megahertz (MHz). As an example, the HF RF generator has an operating frequency of 13.56 MHz or 27 MHz or 60 MHz. It should be noted that the operating frequency of the HF RF generator is greater than the operating frequency of the LF RF generator. The LF RF generator is an example of a primary generator and the HF RF generator is an example of a secondary generator.

The match is a network of circuit components, such as inductors, capacitors, and resistors. For example, the match includes one or more shunt circuits and one or more series circuits. Each shunt circuit has one or more of the circuit components and so does each series circuit. A first branch circuit, which includes one or more shunt circuits or one or more series circuits or a combination thereof, is coupled between an input 410 of the match and an output 414 of the match. Also, a second branch circuit, which includes one or more shunt circuits or one or more series circuits or a combination thereof, is coupled between an input 412 of the match and the output 414.

Examples of the host computer 402 include a desktop computer, a laptop computer, a controller, a tablet, and a smartphone. The host computer 402 includes a processor 406 and a memory device 408. The processor 406 is coupled to the memory device 408. Examples of a processor, as used herein, include a microprocessor, an application specific integrated circuit (ASIC), a programmable logic device (PLD), an integrated microcontroller, and a central processing unit (CPU). Examples of a memory device, as used herein, include a read-only memory (ROM), a random access memory (RAM), a flash memory, a storage disk array, a hard disk, etc.

The plasma chamber 404 includes a substrate support 416, such as an electrostatic chuck (ESC). The ESC includes a lower electrode 418. The plasma chamber 404 further includes a showerhead 420 in which an upper electrode 422 is embedded. Each of the lower electrode 418 and the upper electrode 422 is fabricated from a metal, such as aluminum or an alloy of aluminum. A bottom surface of the showerhead 420 is located above and facing a top surface of the substrate support 416. A substrate S is placed on a top surface of the substrate 416. An example of the substrate S is semiconductor wafer having one or more partially fabricated integrated circuits.

The system 400 further includes a gas source 424 and another, optional, gas source 426. An example of a gas source includes a container for storing one or more chemical compounds. To illustrate, the gas source 424 stores a metal-containing compound such as tungsten hexafluoride and the gas source 426 stores a fluorocarbon. To depict that different compounds or collections of compounds may be used, the figure refers to “Chemistry A” and “Chemistry B.” As another illustration, the gas source 426 stores the chemistry B, the fluorocarbon and nitrogen trifluoride. The system 400 further includes a driver A and a driver B. Examples of a driver include one or more transistors. For example, the driver includes one or more field effect transistors (FETs) that are coupled to each other.

The LF RF generator has an output 428 that is coupled via an RF cable RFC1 to the input 410, which is coupled to the first branch circuit of the match 410. Also, the HF RF generator has an output 430 that is coupled via an RF cable RFC2 to the input 412, which is coupled to the second branch circuit of the match 410. The first and second branch circuits are coupled to each other and to the output 414. The output 414 is coupled via an RF transmission line RFT to the lower electrode 418. The upper electrode 422 is coupled to a reference potential, such as a ground potential.

Also, the processor 406 is coupled to the LF RF generator via a transfer cable TC1 and is coupled to the HF RF generator via a transfer cable TC2. Examples of a transfer cable include a cable that is used for serial transfer of data, a cable used for parallel transfer of data, and a universal serial bus (USB) cable.

The gas source 424 is coupled via a gas supply line 432 to the showerhead 420. Also, the gas source 426 is coupled via a gas supply line 434 to the showerhead 420. Examples of a gas supply line include a gas duct or and a gas tube. The processor 406 is coupled to the driver A and is also coupled to the driver B. The driver A is coupled to a valve 436, which is coupled to the gas supply line 432. For example, the valve 436 is located within the gas supply line 432. Similarly, the driver B is coupled to a valve 437, which is coupled to the gas supply line 434. Examples of a valve include a valve assembly. To illustrate, the valve assembly includes a stationary valve plate and a movable valve plate. The movable valve plate slides with respect to the stationary valve plate. The stationary valve plate has multiple openings. Another illustration of the valve assembly includes a solenoid valve.

The processor 406 generates and provides a recipe signal having a recipe via the transfer cable TC1 to the LF RF generator. An example of the recipe that is provided to the LF RF generator is a frequency level and a parameter level of an LF RF signal 438, such as a sinusoidal signal, to be generated by the LF RF generator. Upon receiving the recipe, the LF RF generator stores the recipe.

Similarly, the processor 406 generates and provides a recipe signal having a recipe via the transfer cable TC2 to the HF RF generator. An example of the recipe that is provided to the HF RF generator is a frequency level and a parameter level of an HF RF signal 440, such as a sinusoidal signal, to be generated by the HF RF generator. Upon receiving the recipe, the HF RF generator stores the recipe.

The processor 406 generates a trigger signal, such as a signal having a single digital pulse, and sends the trigger signal via the transfer cable TC1 to the LF RF generator. Also, the processor 406 sends the trigger signal via the transfer cable TC2 to the HF RF generator.

In response to receiving the trigger signal, the LF RF generator generates the RF signal 438 and sends the RF signal 438 via the output 428 and the RF cable RFC1 to the input 410. Also, in response to receiving the trigger signal, the HF RF generator generates the RF signal 440 and sends the RF signal 440 via the output 430 and the RF cable RFC2 to the input 412.

The first branch circuit of the match 414 receives the RF signal 438 via the input 410 and the second branch circuit of the match 414 receives the RF signal 440 via the input 412. The match 414 modifies impedances of the RF signals 438 and 440 to output first and second modified RF signals. The impedances of the RF signal 438 and 440 are modified by matching an impedance of a load coupled to the output 414 with an impedance of a source coupled to the inputs 410 and 412. An example of the load includes the RF transmission line RFT and the plasma chamber 404. The example of the source includes the RF cables RFC1 and RFC2 and the LF and HF RF generators. The match 414 further combines, such as sums or adds, the first and second modified RF signals to output a modified RF signal 442 at the output 414. The modified RF signal 442 is provided via the RF transmission line RFT to the lower electrode 418.

Moreover, when the modified RF signal 442 is provided to the plasma chamber 404, one or more chemical compounds, including a metal-containing gas, are supplied to the plasma chamber 404. For example, the processor 306 generates and sends a close drive signal to the driver A. Upon receiving the close drive signal, the driver A generates a current signal and provides the current signal to the valve 336 to close the valve 336. To illustrate, when the current signal is supplied to the valve 336 to close the valve 336, a field, such as a magnetic field, is generated to rotate the movable valve plate of the valve 336 with reference to the stationary valve plate of the valve 336 to close all of the openings of the stationary valve plate. When the valve 336 is closed, the chemistry A that is stored within the gas source 324 is not supplied via the gas supply line 332 to the showerhead 320. In this manner, when the valve 336 is closed, the application of chemistry A to the plasma chamber 304 stops.

As another example, the processor 306 generates and sends a completely open drive signal to the driver A. Upon receiving the completely open drive signal, the driver A generates a current signal and provides the current signal to the valve 336 to completely open the valve 336. To illustrate, when the current signal is supplied to the valve 336 to completely open the valve 336, a field, such as a magnetic field, is generated to rotate the movable valve plate of the valve 336 with reference to the stationary valve plate of the valve 336 to open all the openings of the stationary valve plate. When the valve 336 is completely open, the chemistry A that is stored within the gas source 324 is supplied via the gas supply line 332 to the showerhead 320.

As yet another example, the processor 306 generates and sends a partially open drive signal to the driver A. Upon receiving the partially open drive signal, the driver A generates a current signal and provides the current signal to the valve 336 to partially open the valve 336. To illustrate, when the current signal is supplied to the valve 336 to partially open the valve 336, a field, such as a magnetic field, is generated to rotate the movable valve plate of the valve 336 with reference to the stationary valve plate of the valve 336 to open at least one but not all openings or a portion of an opening of the stationary valve plate. When the valve 336 is partially open, the chemistry A that is stored within the gas source 324 is supplied, in a reduced manner, via the gas supply line 332 to the showerhead 320. To illustrate, an amount of chemistry A is supplied in the reduced manner when the amount is substantially less than an amount of chemistry A that is supplied when the valve 336 is completely open. To further illustrate, the amount of chemistry A is substantially less than the amount of chemistry A when the amount of chemistry A is between 0.1% and 10% of the amount of chemistry A when the valve 336 is completely open. In this manner, when the valve 336 is partially open, the application of chemistry A is reduced compared to when the valve 336 is completely open.

In a similar manner, as an example, the processor 306 generates and sends a close drive signal to the driver B. Upon receiving the close drive signal, the driver B generates a current signal and provides the current signal to the valve 337 to close the valve 337. To illustrate, when the current signal is supplied to the valve 337 to close the valve 337, a field, such as a magnetic field, is generated to rotate the movable valve plate of the valve 337 with reference to the stationary valve plate of the valve 337 to close all of the openings of the stationary valve plate. When the valve 337 is closed, the chemistry B that is stored within the gas source 326 is not supplied via the gas supply line 334 to the showerhead 320. In this manner, when the valve 337 is closed, the application of chemistry B stops.

As another example, the processor 306 generates and sends a completely open drive signal to the driver B. Upon receiving the completely open drive signal, the driver B generates a current signal and provides the current signal to the valve 337 to completely open the valve 337. To illustrate, when the current signal is supplied to the valve 337 to completely open the valve 337, the field is generated to rotate the movable valve plate of the valve 337 with reference to the stationary valve plate of the valve 337 to open all of the openings of the stationary valve plate. When the valve 337 is completely open, the chemistry B that is stored within the gas source 326 is supplied via the gas supply line 334 to the showerhead 320.

As yet another example, the processor 306 generates and sends a partially open drive signal to the driver B. Upon receiving the partially open drive signal, the driver B generates a current signal and provides the current signal to the valve 337 to partially open the valve 337. To illustrate, when the current signal is supplied to the valve 337 to partially open the valve 337, a field, such as a magnetic field, is generated to rotate the movable valve plate of the valve 337 with reference to the stationary valve plate of the valve 337 to open at least one but not all openings or a portion of an opening of the stationary valve plate. When the valve 337 is partially open, the chemistry B that is stored within the gas source 326 is supplied, in a reduced manner, via the gas supply line 334 to the showerhead 320. To illustrate, an amount of chemistry B is supplied in the reduced manner when the amount is substantially less than an amount of chemistry B that is supplied when the valve 337 is completely open. To further illustrate, the amount of chemistry B is substantially less than the amount of chemistry B when the amount of chemistry B is between 0.1% and 10% of the amount of chemistry B when the valve 337 is completely open. In this manner, when the valve 337 is partially open, the application of chemistry B is reduced compared to when the valve 337 is completely open.

In some implementations, a controller (optionally implemented via or incorporating the processor and/or host computer in FIG. 4) is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Additional Embodiments

The various hardware and method embodiments described above may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility.

Lithographic patterning of a film typically comprises some or all of the following steps, each step enabled with a number of possible tools: (1) application of photoresist on a workpiece, e.g., a substrate having a silicon nitride film formed thereon, using a spin-on or spray-on tool; (2) curing of photoresist using a hot plate or furnace or other suitable curing tool; (3) exposing the photoresist to visible or UV or x-ray light with a tool such as a wafer stepper; (4) developing the resist so as to selectively remove resist and thereby pattern it using a tool such as a wet bench or a spray developer; (5) transferring the resist pattern into an underlying film or workpiece by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above described processes may be changed. Certain references have been incorporated by reference herein. It is understood that any disclaimers or disavowals made in such references do not necessarily apply to the embodiments described herein. Similarly, any features described as necessary in such references may be omitted in the embodiments herein.

The subject matter of the present disclosure includes all novel and nonobvious combinations and sub-combinations of the various processes, systems and configurations, and other features, functions, acts, and/or properties disclosed herein, as well as any and all equivalents thereof.

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. The above detailed description assumes the embodiments are implemented on a wafer. However, the embodiments are not so limited. The work piece may be of various shapes, sizes, and materials. In addition to semiconductor wafers, other work pieces that may take advantage of the disclosed embodiments include various articles such as printed circuit boards, magnetic recording media, magnetic recording sensors, mirrors, optical elements, micro-mechanical devices and the like. Unless otherwise defined for a particular parameter, the terms “about” and “approximately” as used herein are intended to mean ±10% with respect to a relevant value.

In the above description, numerous specific details are set forth in order to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it is understood that it is not intended to limit the disclosed embodiments.

What is claimed is:

1. A method of etching a feature in a substrate while fabricating an electronic device, the method comprising:
receiving the substrate on a substrate support in a reaction chamber, the substrate comprising a silicon and oxygen containing material under a mask layer having a pattern thereon; and
exposing the substrate to a plasma in the reaction chamber to thereby etch the feature in the silicon and oxygen containing material,
wherein the plasma is generated from a plasma generating gas comprising a metal-containing gas, one or more fluorocarbons, and oxygen,
wherein the plasma is a capacitively-coupled plasma and the substrate is biased,
wherein the capacitively coupled plasma is generated at an excitation frequency between about 13-169 MHz at an RF power level of about 9 kW or less per substrate.

2. The method of claim 1, wherein, while exposing the substrate to the plasma, the substrate is biased at a bias frequency between about 50 kHz and 10 MHz at an RF power level of about 40 kW or less per substrate.

3. The method of claim 1, wherein the capacitively coupled plasma is generated at an RF power level of about 0.2 kW or less per substrate.

4. The method of claim 1, wherein the capacitively coupled plasma is generated at an RF power level of about 0.1 kW or less per substrate.

5. The method of claim 1, wherein the substrate is biased at an RF power level of about 0.5 kW or less per substrate.

6. The method of claim 1, wherein the substrate is biased at an RF power level of about 0.3 kW or less per substrate.

7. The method of claim 1, wherein the plasma generating gas comprises about 0.01 to 10% by volume of a metal halide.

8. The method of claim 1, wherein the plasma generating gas comprises C₄F₈.

9. The method of claim 1, wherein the excitation frequency is about 60 MHz and the bias frequency is about 400 kHz.

10. The method of claim 1, wherein the substrate support is maintained at a temperature of about −100° C. to 150° C. while the substrate is exposed to the plasma

11. The method of claim 1, wherein the silicon and oxygen containing material comprises a silicon oxide.

12. The method of claim 1, wherein the mask layer comprises carbon, polysilicon, silicon nitride, silicon oxynitride, or any combination thereof.

13. The method of claim 1, wherein the feature has a critical dimension of about 200 nm or less in at least 1 direction.

14. The method of claim 1, wherein the etching produces a plurality of features having a feature density of about 1/200 nm⁻¹ or greater in at least 1 direction.

15. The method of claim 1, wherein the feature is etched with a selectivity of the silicon and oxygen containing material to the mask of at least about 0.3.

16. The method of claim 1, wherein the etching produces a plurality of features and the plurality of features have a local critical-dimension uniformity (LCDU) of at most about 100 Å, wherein LCDU is the sample standard deviation (s) of the CDs of the plurality of etched features.

17. The method of claim 1, wherein the metal-containing gas comprises a metal fluoride.

18. The method of claim 17, wherein the metal fluoride comprises rhenium hexafluoride, tungsten hexafluoride, molybdenum hexafluoride, tantalum pentafluoride, vanadium pentafluoride, or any combination thereof.

19. The method of claim 1, wherein the electronic device comprises a memory device.

20. An apparatus for etching a feature in dielectric material on a substrate, the apparatus comprising:
(a) a reaction chamber including:
an inlet for introducing process gases to the reaction chamber,
an outlet for removing material from the reaction chamber,
a substrate support, and
a plasma source configured to provide a plasma to the reaction chamber, the plasma being
a capacitively coupled plasma; and
(b) a controller configured to cause:
receiving the substrate on the substrate support; and
exposing the substrate to a plasma in the reaction chamber to thereby etch the feature in the dielectric material,
wherein the plasma is generated from a plasma generating gas comprising a metal-containing gas, one or more fluorocarbons, and oxygen,
wherein the plasma is a capacitively-coupled plasma and the substrate is biased,
wherein the capacitively coupled plasma is generated at an excitation frequency between about 13-169 MHz at an RF power level of about 9 kW or less per substrate.

21. The apparatus of claim 20, wherein the substrate is biased at a bias frequency between about 50 kHz and 10 MHz at an RF power level of about 40 kW or less per substrate.

22. The apparatus of claim 20, wherein the controller is further configured to cause the capacitively coupled plasma to be generated at an RF power level of about 0.2 kW or less per substrate.

23. The apparatus of claim 20, wherein the controller is further configured to cause the capacitively coupled plasma to be generated at an RF power level of about 0.1 kW or less per substrate.

24. The apparatus of claim 20, wherein the controller is further configured to cause the substrate to be biased at an RF power level of about 0.5 kW or less per substrate.

25. The apparatus of claim 20, wherein the controller is further configured to cause the substrate to be biased at an RF power level of about 0.3 kW or less per substrate.

26. The apparatus of claim 20, wherein the controller is further configured to cause the plasma generating gas to comprise about 0.01 to 10% by volume of a metal halide.

27. The apparatus of claim 20, wherein the controller is further configured to cause the plasma generating gas to comprise C₄F₈.

28. The apparatus of claim 20, wherein the controller is further configured to cause the excitation frequency to be about 60 MHz and the bias frequency to be about 400 kHz.

29. The apparatus of claim 20, wherein the controller is further configured to cause the substrate support to be maintained at a temperature of about −100° C. to 150° C. while the substrate is exposed to the plasma

30. The apparatus of claim 20, wherein the metal-containing gas comprises a metal fluoride.

31. The apparatus of claim 30, wherein the metal fluoride comprises rhenium hexafluoride, tungsten hexafluoride, molybdenum hexafluoride, tantalum pentafluoride, vanadium pentafluoride.
